(19) United States
(12) Patent Application Publication
(10) Pub. No.: US 2026/0318977 A1
(43) Pub. Date: Oct. 15, 2026

(54) MEASUREMENT OF AN INSULATION RESISTANCE OF A VEHICLE ELECTRICAL SYSTEM OF AN ELECTRIC VEHICLE

(71) Applicant: AVL DiTest GmbH, Graz (AT)

(72) Inventors: Patrik Schwaiger, Deutschlandsberg (AT); Christian Huber, Graz (AT); Jonas Schulz, Graz (AT)

(21) Appl. No.: 19/179,931

(22) Filed: Apr. 15, 2025

(30) Foreign Application Priority Data
Apr. 4, 2024 (AT) A50317/2024

(51) Int. Cl. G01R 31/12; B60L 53/16; B60L 53/60; G01R 1/28; G01R 27/14; G01R 31/00

(52) U.S. Cl. CPC G01R 31/1272; B60L 53/16; B60L 53/60; G01R 1/28; G01R 27/14; G01R 31/006

(57) ABSTRACT

In order to measure an effective insulation resistance of the electrical insulation of a high-voltage on-board electrical system of an electric vehicle simply and safely, it is provided that a charging plug of a measuring device is plugged into a charging socket of the electric vehicle, then a charging process of the electric vehicle is initialized with the measuring device, and after initialization of the charging process, the effective insulation resistance (Rw) between at least one charging voltage contact (DC+, DC−) of the charging plug and a reference voltage contact (PE) of the charging plug is measured.

The present invention relates to a method for measuring an effective insulation resistance of a high-voltage on-board electrical system of an electric vehicle. The invention also relates to an arrangement for measuring an effective insulation resistance of a high-voltage on-board electrical system of an electric vehicle.

Electrical insulation of the high-voltage system in the case of electric vehicles, which in the context of this application includes both pure electric vehicles and hybrid vehicles, is an important safety feature. The electrical insulation resistance is a feature of electrical insulation. The electrical insulation of an electric vehicle must therefore be checked regularly, for example as part of the regular vehicle inspection in a workshop. The ohmic resistance between the active conductors (DC+ and DC−) of the high-voltage system and the vehicle body is an essential feature of this electrical insulation. This ohmic resistance is also referred to as insulation resistance.

In order to measure the total insulation of the electric vehicle, both the insulation resistance of the passive high-voltage (HV) components of the electric vehicle, such as the air-conditioning compressor, heater, inverter, etc., and the insulation resistance of the electrical storage system in the electric vehicle must be measured. For this to happen, the HV system in the electric vehicle must be active and the electrical storage system must be electrically connected to the HV components.

Many methods are known for performing a total insulation measurement on the active HV system (e.g. in SAE J1766, ISO 6469-1, ECE-R100). The insulation monitoring devices (IMDs) installed in the vehicle operate according to these established methods. An IMD determines the insulation resistance while the vehicle is in operation. However, the IMD cannot be used during a workshop inspection because the vehicle, and in particular the vehicle's HV system, is inactive in the workshop.

As part of a workshop inspection, it is therefore necessary to measure the insulation resistance by means of an external measuring device. However, checking the vehicle's total insulation with an external measuring device presents significant challenges. Firstly, there is the problem of external access to the HV system in order to be able to contact the HV system with an external measuring device without distorting the insulation measurement. According to the current state of the art, this problem is solved either by exposing the high-voltage contacts (no contact protection) or by using special measuring adapters (with contact protection). In both cases, an installation intervention in the vehicle is necessary. In the first case, there is a significant safety risk for the person performing the measurement, as there is no contact protection. For this reason, the person must wear personal protective equipment, in particular insulating gloves, a helmet with visor, safety shoes and electrical protective clothing. This is hardly feasible in workshop operations. In the other case, vehicle-specific measuring adapters must be used. This means that the workshop must have a suitable measuring adapter for each vehicle. In addition, the measuring adapter must be attached to the vehicle before the measurement. This also makes its use in workshops extremely laborious and time-consuming. Another problem with insulation resistance measurement is that when the HV system is activated, the on-board internal IMD will be active. This means that the measurement value of the insulation resistance can only be determined distorted or can be difficult or even impossible to determine using an external measuring device.

There is therefore a need for a simple external measurement of the insulation resistance on the HV on-board electrical system of an electric vehicle.

This object is achieved by first plugging a charging plug into a charging socket of the electric vehicle, then initializing a charging process of the electric vehicle, and after initializing the charging process, measuring the effective insulation resistance between at least one charging voltage contact of the charging plug and a reference voltage contact of the charging plug. Preferably, the insulation resistance is measured between all charging voltage contacts and the reference voltage contact.

By the initialization of the charging process, the electric vehicle is prompted to close switches that disconnect the charging socket from the high-voltage on-board electrical system. This makes it possible to measure the effective insulation resistance via the charging plug. This eliminates the need for measuring adapters. Instead, a standardized charging plug, which is the same for a wide range of electric vehicles, can be used. This type of measurement also ensures contact protection for the person performing the measurement, thus ensuring personal safety. Thanks to its ease of use, this method is particularly suitable for checking effective insulation resistance in a workshop.

The charging process is advantageously initialized via control contacts on the charging plug, which are connected to the control contacts of the charging socket by the charging plug being plugged into the charging socket, and a predefined charging protocol. This allows the normal charging protocol of the electric vehicle to be used. If necessary, a charging voltage can also be applied between the first charging voltage contact and the second charging voltage contact of the charging plug in order to initialize the charging process.

If a charging voltage is applied to initialize the charging process, the charging voltage will advantageously be switched off before measurement of the effective insulation resistance in order to prevent the battery voltage being superimposed on the charging voltage in the electric vehicle during the measurement.

If an effective insulation resistance is measured between at least one charging voltage contact of the charging plug and a reference voltage contact of the charging plug before initialization of the charging process, a possible moisture problem in the charging socket, which can impair the electrical insulation, can also be detected.

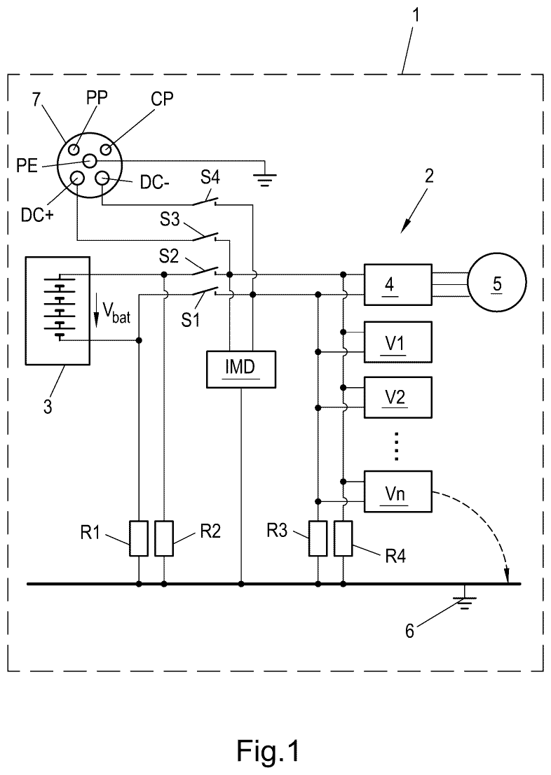

The present invention will be described in greater detail below with reference to FIG. 1 to 5, which by way of example show schematic and non-limiting advantageous embodiments of the invention. In the figures:

FIG. 1 shows an embodiment of a high-voltage on-board electrical system of an electric vehicle,

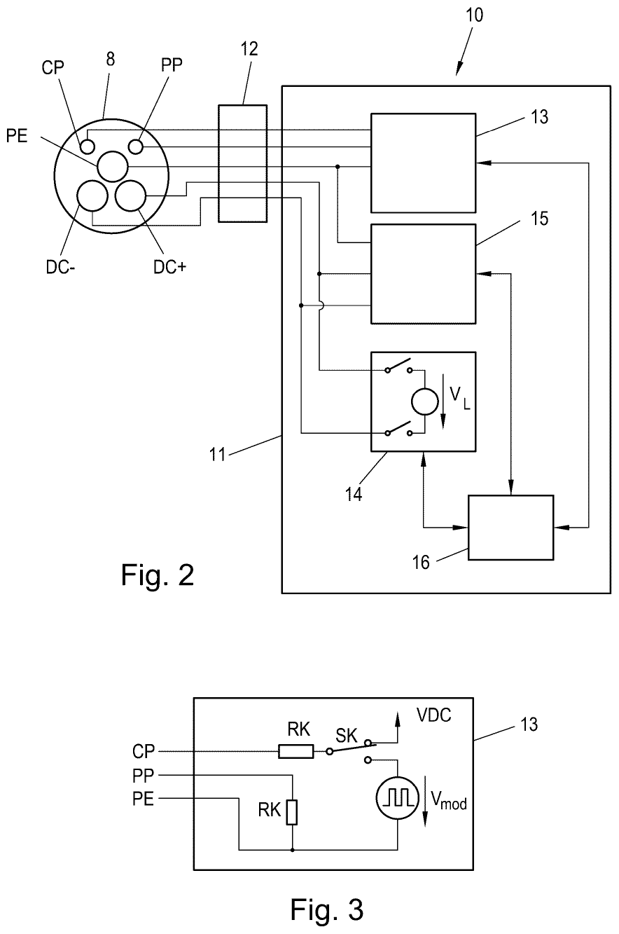

FIG. 2 shows a measuring device for implementing the measuring method according to the invention for measuring the effective insulation resistance of an electric vehicle,

FIG. 3 shows a possible embodiment of a communication module of the measuring device,

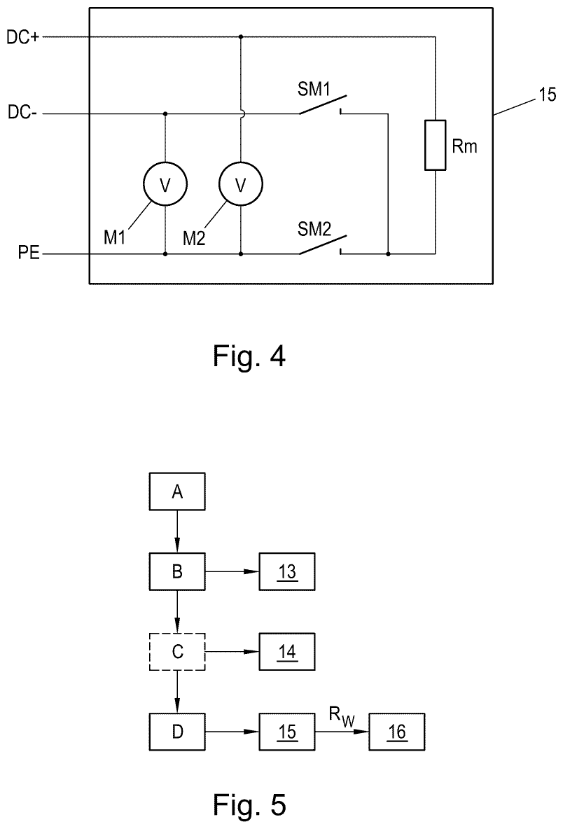

FIG. 4 shows a possible embodiment of a measuring module of the measuring device, and

FIG. 5 shows the sequence according to the invention for measuring the effective insulation resistance.

FIG. 1 shows a typical configuration of a high-voltage on-board electrical system 2 of an electric vehicle 1. For the purposes of the invention, an electric vehicle includes both pure electric vehicles and hybrid vehicles.

The high-voltage on-board electrical system 2 of the electric vehicle 1 comprises an electrical storage battery 3, at least one (often bidirectional) inverter 4 connected to the storage battery 3 and at least one electric motor 5 connected to the inverter 4. During operation of the electric vehicle 1, the inverter 4 converts a direct current (DC) battery voltage V_{bat} into an alternating current (AC) motor voltage Vₘₒₜ in order to drive the electric motor 5 thereby. In case of recuperation, the electric motor 5 can also be operated as a generator and the bidirectional inverter 4 can feed electrical energy into the storage battery 3.

In addition to the inverter 4, the high-voltage on-board electrical system 2 typically includes other electrical consumers Vn, such as an air-conditioning compressor, an electric heater, additional voltage converters, etc. “n” is to be understood as an index that is used when reference is made to consumers in general rather than to a specific consumer. The consumers Vn are also connected to the storage battery 3 and are supplied with electrical energy from the storage battery 3.

For safety reasons, the electrical components of the high-voltage on-board electrical system 2 are connected to an electrical reference point 6 of the electric vehicle 1 via high-resistance insulation resistors R1, R2, R3, R4. If an insulation resistance is generally referenced, Ri is also used with the index “i”. In an electric vehicle 1, the vehicle body typically serves as the electrical reference point (ground) 6. All electrical devices in the electric vehicle 1 are connected to this reference point 6. The high-voltage on-board electrical system 2 is also connected to the electrical reference point 6 via the insulation resistors Ri. When the electric vehicle 1 is in proper working order, the high-resistance insulation resistors Ri ensure that no high voltage is present at the electrical reference point 6 (and thus at the vehicle body, which can be contacted). However, in the event of faults, the actual effective insulation resistance may change. The effective insulation resistance in the electric vehicle 1 must therefore be checked regularly.

In the embodiment according to FIG. 1, an on-board insulation monitoring device IMD is shown, which continuously measures the effective insulation resistance during operation of the electric vehicle 1 and passes it on, for example, to a vehicle control unit for further evaluation.

Due to aging and wear, the electrical insulation may deteriorate, causing the actual effective insulation resistance in the electric vehicle 1 to decrease. This can happen practically anywhere, for example the electrical insulation between the consumer Vn and the electrical reference point 6 can gradually deteriorate, which is indicated in FIG. 1 by the dashed line at the consumer Vn. This naturally affects the insulation resistance measured (e.g. by the insulation monitoring device IMD), usually by the fact that the measured insulation resistance decreases.

The high-voltage on-board electrical system 2 of the electric vehicle 1 also includes switches S1, S2, S3, S4, such as a contactor or relay. If a switch is generally referenced, Sj with the index “j” is also used. First switches S1, S2 serve to disconnect the storage battery 3 from the rest of the high-voltage on-board electrical system 2 as needed, and second switches S3, S4 serve to disconnect a charging socket 7 of the electric vehicle 1 from the rest of the high-voltage on-board electrical system 2 as needed. When the electric vehicle 1 is inactive, the switches Sj are open, in particular the second switches S3, S4 for disconnecting the charging socket 7, and are closed when the electric vehicle 1 is activated. The second switches S3, S4, which connect the charging socket 7 to the high-voltage on-board electrical system 2, are usually only closed during a charging process.

A charging plug 8 is connected to the charging socket 7 in a known manner in order to charge the electric vehicle 1, specifically the storage battery 3 of the electric vehicle 1, externally.

The charging socket 7 has several standardized contacts for this purpose. Firstly, a first charging voltage contact DC+ and a second charging voltage contact DC−, as well as a reference voltage contact PE, are provided on the charging socket 7. The reference voltage contact PE is connected to the electrical reference point 6 in the electric vehicle 1. In addition, two control contacts PP, CP are provided for communication between the charger and the electric vehicle 1. A charging process on the electric vehicle 1 is initialized, carried out and monitored via a standardized charging communication protocol. For this purpose, the charger and the electric vehicle 1 exchange messages according to a charging protocol.

FIG. 2 shows the measuring device 10 according to the invention for externally measuring the effective insulation resistance R_{W} in the high-voltage on-board electrical system 2 of the electric vehicle 1.

The measuring device 10 comprises the charging plug 8 and a measuring unit 11. The charging plug 8 naturally has contacts complementary to the charging socket 7 of the electric vehicle 1. The contacts on the charging socket 7 are usually male and on the charging plug 8 they are female. The charging plug 8 is connected to the measuring unit 11 via a charging cable 12. The charging cable 12 contains lines to connect the individual contacts of the charging plug 8 to the measuring unit 11. The individual lines in the charging cable 12 are where applicable designated corresponding to the designation of the respective contact in the charging plug 8. The charging socket 7 and the charging plug 8 are usually standardized.

The measuring unit 11 comprises various functional modules, which are shown as individual blocks in FIG. 2. However, this is for descriptive purposes only and should not be understood as limiting the hardware or circuit design in the measuring unit 11.

A communication module 13 is connected via control lines to the control contacts PP, CP on the charging plug 8, and also to the reference voltage contact PE. The communication module 13 serves to initialize a charging process with the electric vehicle 1 in order to pretend a charging process using a charger for the electric vehicle 1. For this purpose, the communication module 13 implements the respective standardized charging protocol and generates and sends the corresponding messages to the electric vehicle 1 and evaluates the messages received from the electric vehicle 1.

Typically, initializing a charging process also requires a charging voltage applied to the charging voltage contacts DC+, DC−. For this purpose, a charging voltage module 14 is provided, which generates the required charging voltage and applies it between the charging voltage contacts DC+, DC−. The charging voltage module 14 is therefore connected via charging voltage lines to the first charging voltage contact DC+ and to the second charging voltage contact DC− on the charging plug 8. If no applied charging voltage is required for the initialization of a charging process, the charging voltage module 14 could be omitted or left inactive.

The measuring unit 11 also comprises a measuring module 15 which is connected to the charging voltage contacts DC+, DC− and to the reference voltage contact PE on the charging plug 8. The measuring module 15 measures the voltage between the first charging voltage contact DC+ and the reference voltage contact PE and/or between the second charging voltage contact DC− and the reference voltage contact PE, and uses this to determine the effective insulation resistance R_{W} in the high-voltage on-board electrical system 2 of the electric vehicle 1. This is possible because the measuring module 15 is connected to the high-voltage on-board electrical system 2 via the charging plug 8 and the charging socket 7, and thus the high voltage in the high-voltage on-board electrical system 2 is present at the charging voltage contacts DC+, DC−. In addition to resistance measurement, a current measurement can also be implemented in the measuring module 15. However, how the resistance measurement is specifically implemented in the measuring module 15 is not relevant to the invention.

Last but not least, the measuring unit 11 also comprises a control unit 16 which is connected to and controls the individual functional modules, such as the communication module 13, the measuring module 15 and, if applicable, the charging voltage module 14. The measuring module 15 supplies to the control unit 16 a value representing the effective insulation resistance. The value representing the effective insulation resistance can be the effective insulation resistance R_{W} itself, if the measuring module 11 performs the corresponding evaluation, or it can also be a voltage measurement value and/or current measurement value, or another electrical quantity, if it is the control unit 16 that determines the effective insulation resistance R_{W}.

The control unit 16 is typically designed as microprocessor-based hardware, for example as a microcontroller, with control software running thereon.

Of course, an output unit, such as a display, signal lights, etc., can also be provided on the measuring device 10, for example on the measuring unit 11, in order to display the measured effective insulation resistance R_{W} or to indicate sufficient isolation. A communication interface can also be provided on the measuring device 10, for example on the measuring unit 11, in order to transmit the measured effective insulation resistance R_{W} to another device, either wired or wirelessly.

A possible implementation of the communication module 13 is shown in FIG. 3. Via a switch SK, which is controlled, for example, by the control unit 16, and optional resistors RK (which do not have to be the same), either a supply voltage VDC, for example 12V DC, or a modulated voltage V_{mod}, such as +12V AC voltage with a specified frequency (e.g. 1 kHz), is applied to the control contact CP. The specified charging protocol is implemented by appropriate modulation of the modulated voltage V_{mod}, such as pulse width modulation, frequency modulation or amplitude modulation. The type of modulation is prespecified by the specified charging protocol.

In the charging voltage module 14, for example, a switchable voltage source is provided (as in FIG. 1), which generates the prespecified charging voltage V_{L} and is applied as needed to the charging voltage contacts DC+, DC−, for example via switches controlled by the control unit 16.

For example, a measuring resistor Rm is provided in the measuring module 15, which measuring resistor can be switched via switches SM1, SM2 which can be controlled by the control unit 16, either between the first charging voltage contact DC+ and the reference voltage contact PE or between the second charging voltage contact DC− and the reference voltage contact PE. This allows the respective voltage to be measured via voltage sensors M1, M2. A current sensor could also be provided in the measuring module 15 in order to measure an electrical current flowing, for example, through the measuring resistor Rm.

In order to use the measuring device 10 to measure the insulation resistance R_{W} effective in the high-voltage on-board electrical system 2 of the electric vehicle 1 when the electric vehicle 1 is inactive, the procedure is as follows with reference to FIG. 6.

In a first step A, the measuring device 10 is connected to the charging socket 7 of the electric vehicle 1 via the charging plug 8. In the following step B, a charging process is initialized via the communication module 13. This simulates for the electric vehicle 1 the presence of a charger connected to the charging socket 7. For this purpose, the control unit 16 can give the communication module 13 a corresponding command. The communication module 13 generates the intended standardized messages according to the intended process in order to initialize the intended charging protocol. If a charging voltage is also required at the charging voltage contacts DC+, DC− for the initialization of a charging process, the charging voltage module 14 will generate the required charging voltage in a subsequent step C and apply it to the charging voltage contacts DC+, DC−. The control unit 16 can give the appropriate commands to the charging voltage module 14 at the right time.

The initialization of a charging process causes the electric vehicle 1 to close the switches, in particular the second switches S3, S4, in the high-voltage on-board electrical system 2. The high-voltage on-board electrical system 2 is thus connected to the measuring module 15 via the charging voltage contacts DC+, DC− and the reference voltage contact PE (which is connected to the electrical reference point 6 of the electric vehicle 1 in the electric vehicle 1) and the measuring module 15 can, in step D, determine the measured value representative of the effective insulation resistance R_{W} between a voltage line L+, L− of the high-voltage on-board electrical system 2 and the electrical reference point 6 and transmit it to the control unit 16. Without the initialization of a charging process, the effective insulation resistance R_{W} cannot be measured because switches S3, S4 and normally also S1, S2 would be open.

The measurement of the effective insulation resistance R_{W} thus detects the state of the electrical insulation on the storage battery 3, if the switches S1, S2 are also closed for the charging process, as well as the state of consumers Vn connected to the high-voltage on-board electrical system 2. Hence, the total insulation resistance is measured and it is not possible to determine individual causes of deteriorated insulation. However, this is sufficient for the purpose of regularly checking the insulation resistance of the high-voltage on-board electrical system 2 of an electric vehicle 1 in a workshop.

If a charging voltage was applied to the charging voltage contacts DC+, DC− in order to initialize the charging process, the applied charging voltage is switched off again before the measurement of the effective insulation resistance R_{W}. The battery voltage V_{bat} is then applied to the charging voltage contacts DC+, DC− and the effective insulation resistance R_{W} can be measured using the battery voltage V_{bat}. This can also be done in step C, for example, and can be controlled accordingly by the control unit 16.

In principle, the effective insulation resistance R_{W} could also be measured with charging voltage applied. In this case, the charging voltage would not have to be switched off for measuring the effective insulation resistance R_{W}. However, it would have to be taken into account that in this case, two voltage sources (storage battery 3, charging voltage module 14), or rather their voltages, are superimposed. This can lead to distorted measurements or other unintended effects, which is why it is advantageous and easier to switch off the charging voltage before measuring, if necessary, and then measure with the battery voltage V_{bat}.

Switching off the charging voltage does not immediately interrupt the charging process in the electric vehicle 1, which can be exploited in order to measure the effective insulation resistance R_{W} (which can be carried out very quickly in any case). In particular, the switches Sm are not closed immediately. If necessary, the communication module 13 can also signal to the electric vehicle 1 that the charging process has not yet ended.

An on-board insulation monitoring device (IMD) is deactivated by default during the charging process. This prevents the IMD from interfering with the external measurement of the effective insulation resistance R_{W}.

The invention thus uses a simulated charging process for measuring the effective insulation resistance R_{W} in the high-voltage on-board electrical system 2 of the electric vehicle 1. For this measurement, nothing needs to be modified or installed on the electric vehicle 1. Instead, a standardized charging plug of the electric vehicle 1 that fits the charging socket can be used. This makes the measurement not only safe, because it provides protection against accidental contact, but also extremely simple.

The measurement of the effective insulation resistance R_{W} according to the invention is carried out using DC charging as an example, as this is usual in pure electric vehicles. In hybrid vehicles, charging is often provided via an AC voltage and an on-board charger. The on-board charger would prevent the effective insulation resistance of the high-voltage on-board electrical system of the electric vehicle 1 from being measured externally because the on-board charger is arranged between the electrical system and the charging socket. If it is possible to bypass the charging inverter in order to measure the effective insulation resistance R_{W}, then it could also be measured in such an electric vehicle 1 according to the invention. In this case, a charging socket 7 and associated charging plug 8 with a different contact assignment would naturally also be used. In particular, instead of the first charging voltage contact DC+ and second charging voltage contact DC− for DC charging, charging voltage contacts for AC charging would be provided, such as at least one phase conductor L1, L2, L3 and one neutral conductor N (not shown).

After measuring the effective insulation resistance R_{W}, which can usually be performed very quickly, the simulated charging process is terminated, preferably according to the prespecified charging protocol. For this purpose, the communication module 13, controlled, for example, by the control unit 16, can send the intended messages to the electric vehicle 1 and/or process received messages. If the charging process is not terminated by the measuring device 10, but for example, the charging plug 8 is simply removed after the measurement, the electric vehicle 1 will exit the charging process after a certain period of time or when it is put into operation and open the switches Sj again.

Another frequently required measurement can be performed using the measuring device 10. In order to detect moisture problems in the charging socket 7 of an electric vehicle 1, an insulation measurement is often performed on the charging socket 7 before the charging process is initialized. In this case, the switches S3, S4 connecting the charging socket 7 to the high-voltage on-board electrical system 2 are opened. The insulation resistance can then be measured between at least one, preferably between each, charging voltage contact of the charging socket 7, DC+, DC− for DC charging or L1, L2 L3, N (not shown) for AC charging, and the reference voltage contact PE.

1. A method for measuring an effective insulation resistance (Rw) of a high-voltage on-board electrical system of an electric vehicle, comprising the following steps:
inserting a charging plug of a measuring device into a charging socket of the electric vehicle;
initializing a charging process of the electric vehicle by the measuring device; and
measuring with the measuring device, after initializing the charging process, the effective insulation resistance between at least one charging voltage contact of the charging plug and a reference voltage contact of the charging plug.

2. The method according to claim 1, wherein the charging process is initialized via control contacts on the charging plug, which are connected to control contacts of the charging socket by plugging the charging plug into the charging socket, and a prespecified charging protocol.

3. The method according to claim 1, wherein in order to initialize the charging process, a charging voltage is additionally applied between a first charging voltage contact and a second charging voltage contact of the charging plug.

4. The method according to claim 3, wherein the charging voltage is switched off before measurement of the effective insulation resistance.

5. The method according to claim 1, wherein before initialization of the charging process, an effective insulation resistance is measured between at least one charging voltage contact of the charging plug and a reference voltage contact of the charging plug.

6. An arrangement for measuring an effective insulation resistance of a high-voltage on-board electrical system of an electric vehicle, comprising:
the electric vehicle with a charging socket and a measuring device with a charging plug, wherein the charging plug is plugged into the charging socket;
a measuring unit with a communication module and a measuring module being provided in the measuring device, wherein the communication module is provided to initialize a charging process on the electric vehicle, and, after initialization of the charging process, the measuring module is provided to measure the effective insulation resistance between at least one charging voltage contact of the charging plug and a reference voltage contact of the charging plug.

7. The arrangement according to claim 6, wherein a charging voltage module is additionally provided in the measuring unit, which charging voltage module is configured for generating a charging voltage between a first charging voltage contact and a second charging voltage contact of the charging plug for initializing the charging process.
